(19) United States
(12) Patent Application Publication
(10) Pub. No.: US 2019/0267307 A1
(43) Pub. Date: Aug. 29, 2019

(54) HEAT CONDUCTIVE WIRING BOARD AND SEMICONDUCTOR ASSEMBLY USING THE SAME

(71) Applicant: BRIDGE SEMICONDUCTOR CORP., Taipei City (TW)

(72) Inventors: Charles W. C. LIN, Taipei City (TW); Chia-Chung WANG, Taipei City (TW)

(21) Appl. No.: 16/411,949

(22) Filed: May 14, 2019

Related U.S. Application Data
(63) Continuation-in-part of application No. 16/400,879, filed on May 1, 2019, now abandoned.
Application No. 16/400,879 is a continuation-in-part of application No. 15/605,920, filed on May 25, 2017, now abandoned.
Application No. 15/605,920 is a continuation-in-part of application No. 15/881,119, filed on Jan. 26, 2018.
Application No. 15/605,920 is a continuation-in-part of application No. 14/621,332, filed on Feb. 12, 2015, now abandoned.
Application No. 14/621,332 is a continuation-in-part of application No. 14/846,987, filed on Sep. 7, 2015.
Application No. 15/881,119 is a continuation-in-part of application No. 15/605,920, filed on May 25, 2017, now abandoned.
Application No. 15/605,920 is a continuation-in-part of application No. 14/621,332, filed on Feb. 12, 2015, now abandoned.
Application No. 14/621,332 is a continuation-in-part of application No. 14/846,987, filed on Sep. 7, 2015.
Application No. 14/846,987 is a continuation-in-part of application No. 14/621,332, filed on Feb. 12, 2015, now abandoned.
(60) Provisional application No. 61/949,652, filed on Mar. 7, 2014.

(51) Int. Cl. H01L 23/373; H01L 23/498

(52) U.S. Cl. CPC H01L 23/3737; H01L 23/49838; H01L 23/49827

(57) ABSTRACT

The wiring board mainly includes a heat dissipation slug, core substrate and a modified binding matrix. The modified binding matrix provides mechanical bonds between the heat dissipation slug and the core substrate disposed about the peripheral sidewall of the heat dissipation slug. The modified binding matrix contains low CTE modulators dispensed in a resin adhesive to alleviate resin internal expansion and shrinkage, thereby significantly reducing the risk of the resin cracking.

### CROSS REFERENCE TO RELATED APPLICATIONS

This application is a continuation-in-part of U.S. application Ser. No. 16/400,879 filed May 1, 2019. The U.S. application Ser. No. 16/400,879 is a continuation-in-part of U.S. application Ser. No. 15/605,920 filed May 25, 2017 and a continuation-in-part of U.S. application Ser. No. 15/881,119 filed Jan. 26, 2018. The U.S. application Ser. No. 15/605,920 is a continuation-in-part of U.S. application Ser. No. 14/621,332 filed Feb. 12, 2015 and a continuation-in-part of U.S. application Ser. No. 14/846,987 filed Sep. 7, 2015. The U.S. application Ser. No. 15/881,119 is a continuation-in-part of U.S. application Ser. No. 15/605,920 filed May 25, 2017, a continuation-in-part of U.S. application Ser. No. 14/621,332 filed Feb. 12, 2015 and a continuation-in-part of U.S. application Ser. No. 14/846,987 filed Sep. 7, 2015. The U.S. application Ser. No. 14/846,987 is a continuation-in-part of U.S. application Ser. No. 14/621,332 filed Feb. 12, 2015. The U.S. application Ser. No. 14/621,332 claims the benefit of filing date of U.S. Provisional Application Ser. No. 61/949,652 filed Mar. 7, 2014. The entirety of each of said Applications is incorporated herein by reference.

### FIELD OF THE INVENTION

The present invention relates to a wiring board and, more particularly, to a heat conductive wiring board and a semiconductor assembly using the same.

### DESCRIPTION OF RELATED ART

High performance microprocessors and ASICs require high performance wiring board for signal interconnection. However, as the power increases, large amount of heat generated by semiconductor chip would degrade device performance and impose thermal stress on the chip. U.S. Pat. No. 8,859,908 to Wang et al., U.S. Pat. No. 8,415,780 to Sun, U.S. Pat. No. 9,185,791 to Wang and U.S. Pat. No. 9,706,639 to Lee disclose various package boards in which a heat dissipation slug is disposed in an aperture of a substrate so that the heat generated by semiconductor chip can be dissipated directly through the underneath heat dissipation slug. As shown in FIG. 1, the heat dissipation slug 12 is bonded to the surrounding substrate 14 through an adhesive 17 therebetween. However, as resin adhesive is prone to crack when confined in a very narrow space and under stringent operational requirements, these wiring boards are unreliable for practical usage.

In view of the various development stages and limitations in current boards, fundamentally improving board's thermo-mechanical property is highly desirable.

### SUMMARY OF THE INVENTION

An objective of the present invention is to provide a wiring board having modulators dispensed in a resin adhesive to form a modified binding matrix with a sufficient width for attaching a heat dissipation slug to a surrounding core substrate and effectively releasing thermo-mechanical induced stress. By adjusting a coefficient of thermal expansion (CTE) of the modified binding matrix to be lower than 40 ppm/° C., the internal stress of the modified binding matrix during thermal cycling in a confined space can be effectively alleviated, thereby significantly reducing the failure risk of the wiring board.

In accordance with the foregoing and other objectives, the present invention provides a heat conductive wiring board, comprising: a core substrate having a top circuit layer at a top surface thereof, a bottom circuit layer at a bottom surface thereof and an aperture extending from the top surface to the bottom surface thereof; a heat dissipation slug disposed in the aperture of the core substrate; a resin adhesive that has a first coefficient of thermal expansion and fills a gap between a peripheral sidewall of the heat dissipation slug and an inner sidewall of the aperture; and a plurality of modulators that have a second coefficient of thermal expansion lower than the first coefficient of thermal expansion and are dispensed in the resin adhesive to form a modified binding matrix having a width of more than 10 micrometers in the gap, wherein a coefficient of thermal expansion of the modified binding matrix is lower than 40 ppm/° C.

In another aspect, the modified binding matrix may extend outside of the gap and further cover the top surface of the core substrate and the bottom surface of the core substrate as well as a bottom side of the heat dissipation slug, and the wiring board further comprises a top routing trace and a bottom routing trace, wherein (i) the modified binding matrix has an inner sidewall that laterally surrounds a cavity from which a top side of the heat dissipation slug is exposed, (ii) the top routing trace is disposed over the modified binding matrix and electrically coupled to the top circuit layer of the core substrate, and (iii) the bottom routing trace is disposed under the modified binding matrix and electrically coupled to the bottom circuit layer of the core substrate and thermally conductible to the bottom side of the heat dissipation slug.

In yet another aspect, the wiring board further comprises a top crack inhibiting structure, a top routing trace, a bottom crack inhibiting structure and a bottom routing trace, wherein (i) the top crack inhibiting structure covers the top surface of the core substrate and has an inner sidewall that laterally surrounds a cavity from which a top side of the heat dissipation slug is exposed, (ii) the top routing trace is disposed over the top crack inhibiting structure and electrically coupled to the top circuit layer of the core substrate, (iii) the bottom crack inhibiting structure covers the bottom surface of the core substrate, a bottom side of the heat dissipation slug and a bottom surface of the modified binding matrix, and (iv) the bottom routing trace is disposed under the bottom crack inhibiting structure and electrically coupled to the bottom circuit layer of the core substrate and thermally conductible to the bottom side of the heat dissipation slug.

Additionally, the present invention also provides a semiconductor assembly that includes a semiconductor device electrically coupled to the aforementioned wiring board and disposed in the cavity laterally surrounded by the modified binding matrix or/and the top crack inhibiting structure and mounted on the heat dissipation slug.

These and other features and advantages of the present invention will be further described and more readily apparent from the detailed description of the preferred embodiments which follows.

### BRIEF DESCRIPTION OF THE DRAWINGS

The following detailed description of the preferred embodiments of the present invention can best be understood when read in conjunction with the following drawings, in which:

FIG. 1 is a cross-sectional view of a conventional wiring board;

FIGS. 2 and 3 are cross-sectional and top perspective views, respectively, of a core substrate in accordance with the first embodiment of the present invention;

FIGS. 4 and 5 are cross-sectional and top perspective views, respectively, of the structure of FIGS. 2 and 3 further provided with a heat dissipation slug in accordance with the first embodiment of the present invention;

FIGS. 6 and 7 are cross-sectional and top perspective views, respectively, of the structure of FIGS. 4 and 5 further provided with a modified binding matrix to finish the fabrication of a wiring board in accordance with the first embodiment of the present invention;

FIG. 8 is a cross-sectional view of another aspect of the wiring board in accordance with the first embodiment of the present invention;

FIGS. 9 and 10 are cross-sectional and top perspective views, respectively, of yet another aspect of the wiring board in accordance with the first embodiment of the present invention;

FIG. 11 is a cross-sectional view of a wiring board in accordance with the second embodiment of the present invention;

FIG. 12 is a cross-sectional view of another aspect of the wiring board in accordance with the second embodiment of the present invention;

FIG. 13 is a cross-sectional view of a wiring board in accordance with the third embodiment of the present invention;

FIG. 14 is a cross-sectional view of another aspect of the wiring board in accordance with the third embodiment of the present invention;

FIG. 15 is a cross-sectional view of yet another aspect of the wiring board in accordance with the third embodiment of the present invention;

FIG. 16 is a cross-sectional view of a semiconductor assembly having a semiconductor device electrically connected to the wiring board of FIG. 15 in accordance with the third embodiment of the present invention;

FIG. 17 is a cross-sectional view of a wiring board in accordance with the fourth embodiment of the present invention;

FIG. 18 is a cross-sectional view of another aspect of the wiring board in accordance with the fourth embodiment of the present invention;

FIG. 19 is a cross-sectional view of yet another aspect of the wiring board in accordance with the fourth embodiment of the present invention;

FIG. 20 is a cross-sectional view of a semiconductor assembly having a semiconductor device electrically connected to the wiring board of FIG. 19 in accordance with the fourth embodiment of the present invention;

FIG. 21 is a cross-sectional view of a wiring board in accordance with the fifth embodiment of the present invention;

FIG. 22 is a cross-sectional view of another aspect of the wiring board in accordance with the fifth embodiment of the present invention;

FIG. 23 is a cross-sectional view of a semiconductor assembly having a semiconductor device electrically connected to the wiring board of FIG. 22 in accordance with the fifth embodiment of the present invention;

FIG. 24 is a cross-sectional view of a wiring board in accordance with the sixth embodiment of the present invention;

FIG. 25 is a cross-sectional view of another aspect of the wiring board in accordance with the sixth embodiment of the present invention;

FIG. 26 is a cross-sectional view of a semiconductor assembly having a semiconductor device electrically connected to the wiring board of FIG. 25 in accordance with the sixth embodiment of the present invention;

FIG. 27 is a cross-sectional view of a wiring board in accordance with the seventh embodiment of the present invention;

FIG. 28 is a cross-sectional view of another aspect of the wiring board in accordance with the seventh embodiment of the present invention;

FIG. 29 is a cross-sectional view of a semiconductor assembly having a semiconductor device electrically connected to the wiring board of FIG. 28 in accordance with the seventh embodiment of the present invention;

FIG. 30 is a cross-sectional view of yet another aspect of the wiring board in accordance with the sixth seventh embodiment of the present invention; and

FIG. 31 is a cross-sectional view of a semiconductor assembly having a semiconductor device electrically connected to the wiring board of FIG. 30 in accordance with the seventh embodiment of the present invention.

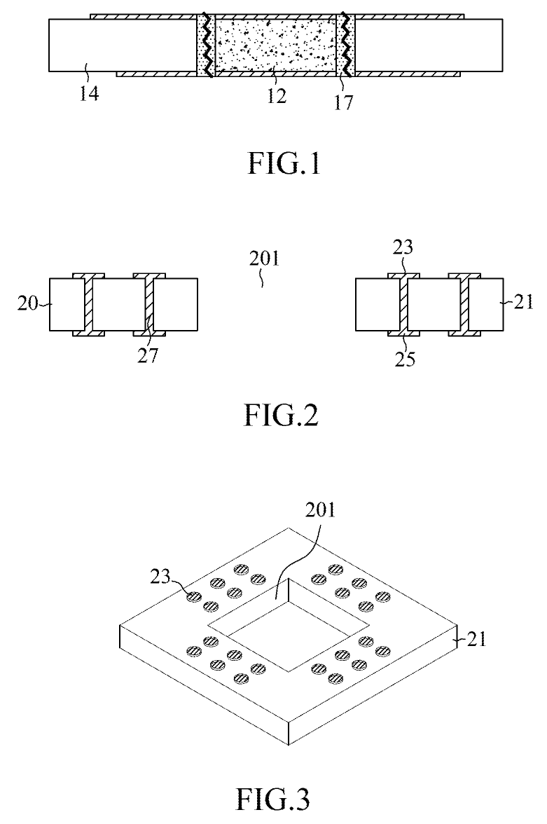

### DETAILED DESCRIPTION OF THE PREFERRED EMBODIMENTS

Hereafter, examples will be provided to illustrate the embodiments of the present invention. Advantages and effects of the invention will become more apparent from the following description of the present invention. It should be noted that these accompanying figures are simplified and illustrative. The quantity, shape and size of components shown in the figures may be modified according to practical conditions, and the arrangement of components may be more complex. Other various aspects also may be practiced or applied in the invention, and various modifications and variations can be made without departing from the spirit of the invention based on various concepts and applications.

### Embodiment 1

FIGS. 2-7 are schematic views showing a method of making a wiring board that includes a core substrate, a heat dissipation slug and a modified binding matrix in accordance with the first embodiment of the present invention.

FIGS. 2 and 3 are cross-sectional and top perspective views, respectively, of a core substrate 20. The core substrate 20 has an aperture 201 extending from its top surface and its bottom surface. The aperture 201 can be formed by numerous techniques, such as punching, drilling or laser cutting. In this illustration, the core substrate 20 includes an insulating core 21, a top circuit layer 23, a bottom circuit layer 25 and metallized through holes 27. The top circuit layer 23 and the bottom circuit layer 25 typically are patterned copper layers at the top and bottom surfaces, respectively, of the insulating core 21. The metallized through holes 27 extend through the insulating core 21 to provide electrical connections between the top circuit layer 23 and the bottom circuit layer 25.

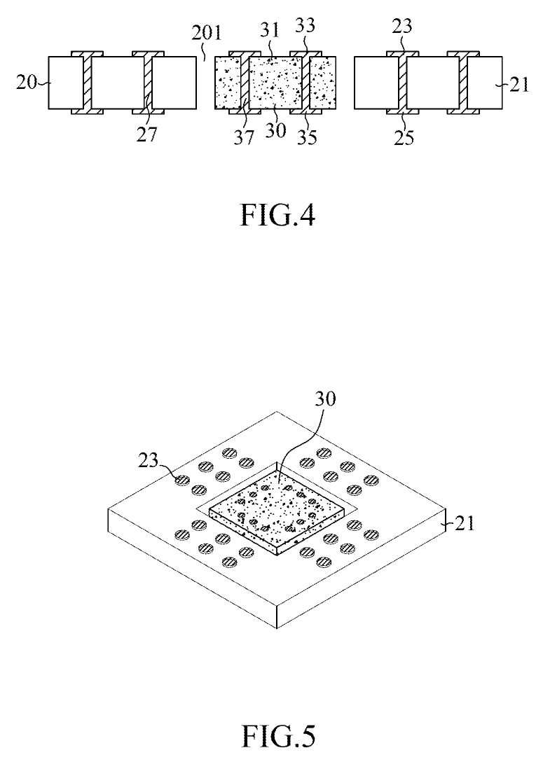

FIGS. 4 and 5 are cross-sectional and top perspective views, respectively, of the structure with a heat dissipation slug 30 inserted into the aperture 201 of the core substrate 20. The heat dissipation slug 30 has a thickness substantially equal to that of the core substrate 20, and is spaced from an inner sidewall of the aperture 201 of the core substrate 20. In this illustration, the heat dissipation slug 30 includes an electrical isolator 31, a top metal layer 33, a bottom metal layer 35, and metallized through vias 37. The top metal layer 33 and the bottom metal layer 35 typically are patterned copper layers at the top and bottom sides, respectively, of the electrical isolator 31. The metallized through vias 37 extend through the electrical isolator 31 to provide electrical connections between the top metal layer 33 and the bottom metal layer 35. For heat dissipation, the electrical isolator 31 typically is made of a thermally conductive material. Preferably, the heat dissipation slug 30 has a thermal conductivity higher than 10 W/mk. Additionally, for flip-chip assembly application, the heat dissipation slug 30 may have a coefficient of thermal expansion (CTE) lower than 10 ppm/° C. (for example, 2×10⁻⁶ K⁻¹ to 10'10⁻⁶ K⁻¹) so that solder cracking defects caused by CTE mismatch between a flipped chip (not shown in the figure) and heat dissipation slug 30 can be alleviated.

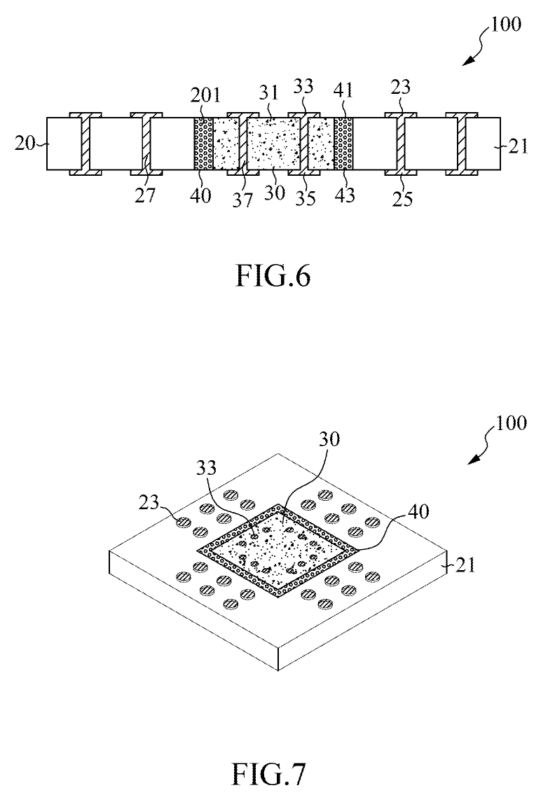

FIGS. 6 and 7 are cross-sectional and top perspective views, respectively, of the structure provided with a modified binding matrix 40 in the gap between the peripheral sidewall of the heat dissipation slug 30 and the inner sidewall of the aperture 201. The modified binding matrix 40 includes a resin adhesive 41 and a plurality of modulators 43 dispensed in the resin adhesive 41, and laterally covers and surrounds and conformally coats the inner sidewall of the core substrate 20 and the peripheral sidewall of the heat dissipation slug 30. The resin adhesive 41 typically has a coefficient of thermal expansion higher than those of the core substrate 20 and the heat dissipation slug 30, and fills the gap between the core substrate 20 and the heat dissipation slug 30. In order to effectively reduce the risk of resin cracking, the modulators 43 has a coefficient of thermal expansion (CTE) lower than that of the resin adhesive 41. Preferably, the CTE of the modulators 43 is lower by at least 10 ppm/° C. than that of the resin adhesive 41 so as to exhibit significant effect. In this embodiment, the modified binding matrix 40 contains the modulators 43 in an amount of at least 30% by volume based on the total volume of the gap. As a result, the internal expansion and shrinkage of the modified binding matrix 40 during thermal cycling can be alleviated so as to restrain its cracking. Additionally, for effectively releasing thermo-mechanical induced stress, the modified binding matrix 40 preferably has a sufficient width of more than 10 micrometers (more preferably 25 micrometers or more) in the gap to absorb the stress.

Accordingly, a wiring board 100 is accomplished and includes the core substrate 20, the heat dissipation slug 30 and the modified binding matrix 40. The heat dissipation slug 30 can provide an effective heat dissipation pathway for chip assembled thereon, thereby enhancing thermal performance of the assembly. The core substrate 20 is bonded around the peripheral sidewall of the heat dissipation slug 30 by the modified binding matrix 40, and provides electrical contacts at its two opposite sides and vertical connection channels. The modified binding matrix 40 provides robust mechanical bonds between the core substrate 20 and the heat dissipation slug 30, and includes low CTE modulators 43 in the resin adhesive 41 to reduce the risk of cracking induced by serious internal expansion and shrinkage.

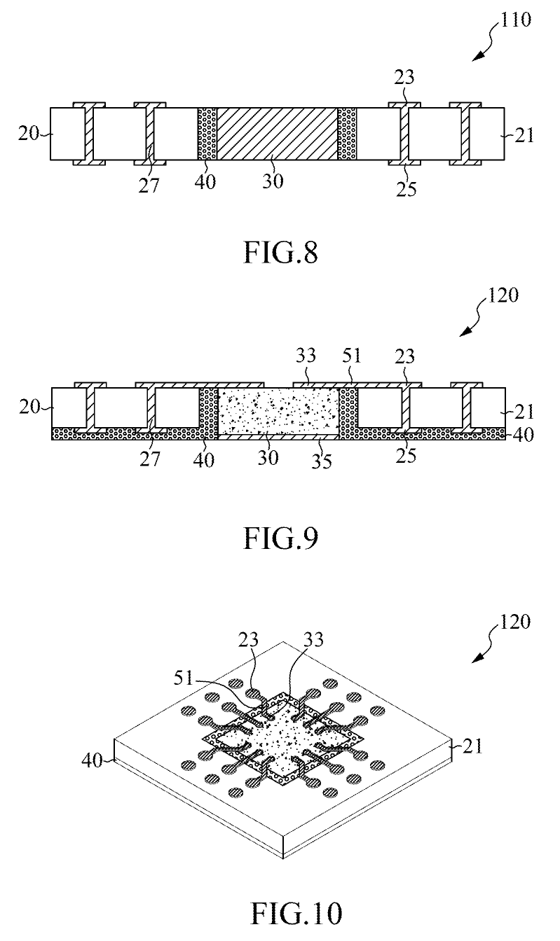

FIG. 8 is a cross-sectional view of another aspect of the wiring board in accordance with the first embodiment of the present invention. The wiring board 110 is similar to that illustrated in FIG. 6, except that the heat dissipation slug 30 is made of metal.

FIGS. 9 and 10 are cross-sectional and top perspective views, respectively, of yet another aspect of the wiring board in accordance with the first embodiment of the present invention. The wiring board 120 is similar to that illustrated in FIGS. 6 and 7, except that (i) it further includes a top plated layer 51 for electrical connection between the top metal layer 33 of the heat dissipation slug 30 and the top circuit layer 23 of the core substrate 20, (ii) the bottom metal layer 35 of the heat dissipation slug 30 is an unpatterned metal layer and no metallized through vias in the heat dissipation slug 30, and (iii) the thickness of the core substrate 20 is less than that of the heat dissipation slug 30, and (iv) the modified binding matrix 40 extends outside of the gap and further covers the bottom surface of the core substrate 20. The top plated layer 51 laterally extends on the modified binding matrix 40 in the gap, and further laterally extends over the top surface of the core substrate 20 and the top side of the heat dissipation slug 30 to be electrically coupled to the top metal layer 33 and the top circuit layer 23.

### Embodiment 2

FIG. 11 is a cross-sectional view of a wiring board in accordance with the second embodiment of the present invention.

For purposes of brevity, any description in Embodiment 1 is incorporated herein insofar as the same is applicable, and the same description need not be repeated.

The wiring board 200 is similar to that illustrated in FIG. 6, except that (i) the thickness of the core substrate 20 is less than that of the heat dissipation slug 30, (ii) the modified binding matrix 40 extends outside of the gap and further covers the top surface of the core substrate 20, and (iii) the wiring board 200 further includes a top routing trace 71 formed over the modified binding matrix 40 from above by metal deposition and metal patterning process. The top routing trace 71 is a patterned metal layer and typically made of copper. The top routing trace 71 laterally extends on the modified binding matrix 40 and contacts the top circuit layer 23 of the core substrate 20 through top metal vias 714 in the modified binding matrix 40. As a result, the top routing trace 71 is electrically connected to the top circuit layer 23 of the core substrate 20 through the top metal vias 714 penetrating through the modified binding matrix 40.

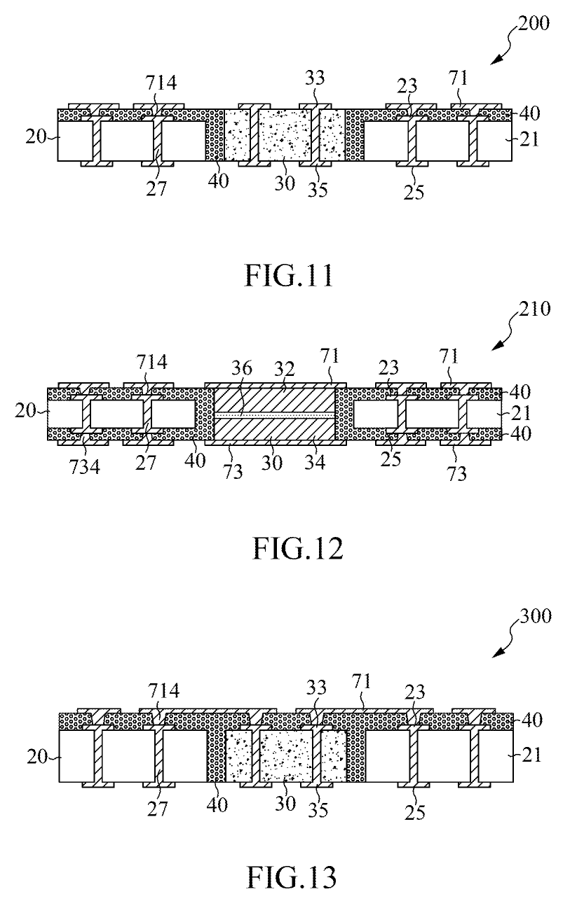

FIG. 12 is a cross-sectional view of another aspect of the wiring board in accordance with the second embodiment of the present invention. The wiring board 210 is similar to that illustrated in FIG. 11, except that (i) the heat dissipation slug 30 includes a top metal block 32, a bottom metal block 34 and a thermally conductive and electrically insulating film 36 between the top metal block 32 and the bottom metal block 34, (ii) the modified binding matrix 40 further covers the bottom surface of the core substrate 20, and (iii) the wiring board 210 may optionally further include a bottom routing trace 73 formed under the modified binding matrix 40 from below by metal deposition and metal patterning process. The bottom routing trace 73 is a patterned metal layer and typically made of copper. The bottom routing trace 73 laterally extends under the modified binding matrix 40 and contacts the bottom circuit layer 25 of the core substrate 20 through bottom metal vias 734 in the modified binding matrix 40. As a result, the bottom routing trace 73 is electrically connected to the bottom circuit layer 25 of the core substrate 20 through the bottom metal vias 734 penetrating through the modified binding matrix 40. Additionally, in this illustration, the top routing trace 71 has a selected portion laterally extending over the top metal block 32, whereas the bottom routing trace 73 has a selected portion laterally extending under the bottom metal block 34.

### Embodiment 3

FIG. 13 is a cross-sectional view of a wiring board in accordance with the third embodiment of the present invention.

For purposes of brevity, any description in the Embodiments above is incorporated herein insofar as the same is applicable, and the same description need not be repeated.

The wiring board 300 is similar to that illustrated in FIG. 6, except that the modified binding matrix 40 extends outside of the gap and further covers the top surface of the core substrate 20 and the top side of the heat dissipation slug 30, and the wiring board 300 further includes a top routing trace 71 formed over the modified binding matrix 40 from above. The top routing trace 71 laterally extends above the core substrate 20 and the heat dissipation slug 30 and contacts the top circuit layer 23 of the core substrate 20 and the top metal layer 33 of the heat dissipation slug 30 through top metal vias 714 in the modified binding matrix 40. As a result, the top routing trace 71 is thermally conductible to the heat dissipation slug 30 and electrically connected to the top circuit layer 23 of the core substrate 20 and the top metal layer 33 of the heat dissipation slug 30 through the top metal vias 714.

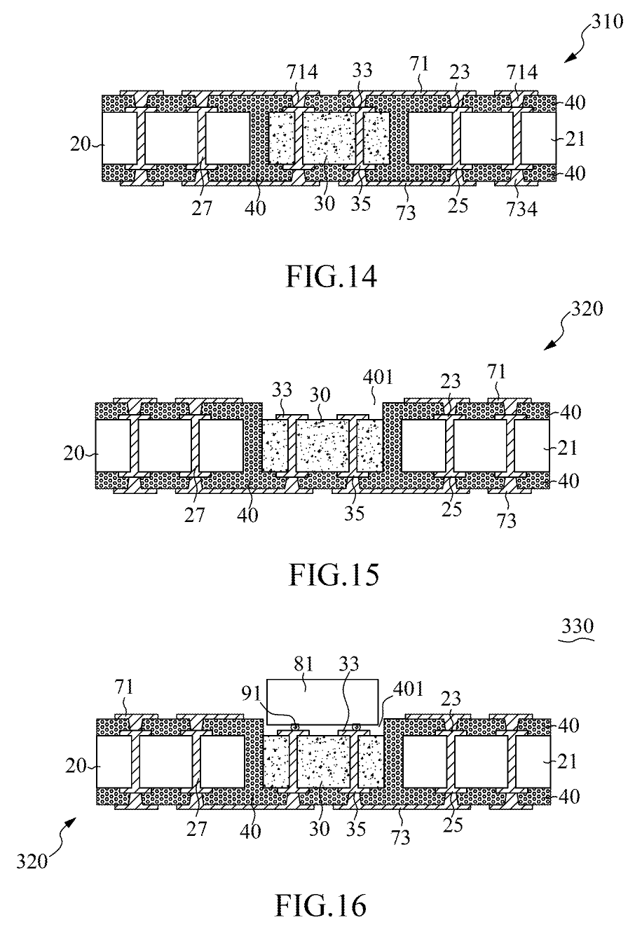

FIG. 14 is a cross-sectional view of another aspect of the wiring board in accordance with the third embodiment of the present invention. The wiring board 310 is similar to that illustrated in FIG. 13, except that the modified binding matrix 40 further covers the bottom surface of the core substrate 20 and the bottom side of the heat dissipation slug 30, and the wiring board 310 further includes a bottom routing trace 73 formed under the modified binding matrix 40 from below. The bottom routing trace 73 laterally extends below the core substrate 20 and the heat dissipation slug 30 and contacts the bottom circuit layer 25 of the core substrate 20 and the bottom metal layer 35 of the heat dissipation slug 30 through bottom metal vias 734 in the modified binding matrix 40. As a result, the top routing trace 71 is thermally conductible to and electrically connected to the bottom routing traces 73 through the core substrate 20 and the heat dissipation slug 30.

FIG. 15 is a cross-sectional view of yet another aspect of the wiring board in accordance with the third embodiment of the present invention. The wiring board 320 is similar to that illustrated in FIG. 14, except that the top side of the heat dissipation slug 30 is exposed from above. In this illustration, a selected portion of the modified binding matrix 40 is removed to form a cavity 401 aligned with the heat dissipation slug 30. As a result, the modified binding matrix 40 has an inner sidewall that laterally surrounds the cavity 401 from which the top surface of the heat dissipation slug 30 is exposed for device connection. In this aspect, the heat dissipation slug 30 preferably has an elastic modulus higher than 200 GPa, so that the high stiffness of the heat dissipation slug 30 can help to maintain the flatness of the wiring board 320.

FIG. 16 is a cross-sectional view of a semiconductor assembly 330 with a semiconductor device 81 electrically connected to the wiring board 320 illustrated in FIG. 15. The semiconductor device 81, illustrated as a bare chip, is face-down disposed into the cavity 401 and mounted on the top metal layer 33 of the heat dissipation slug 30 through bumps 91. As a result, the semiconductor device 81 is electrically connected to the wiring board 320 through the bumps 91, and the heat generated by the semiconductor device 81 can be conducted away through the heat dissipation slug 30 and the bottom routing trace 73.

### Embodiment 4

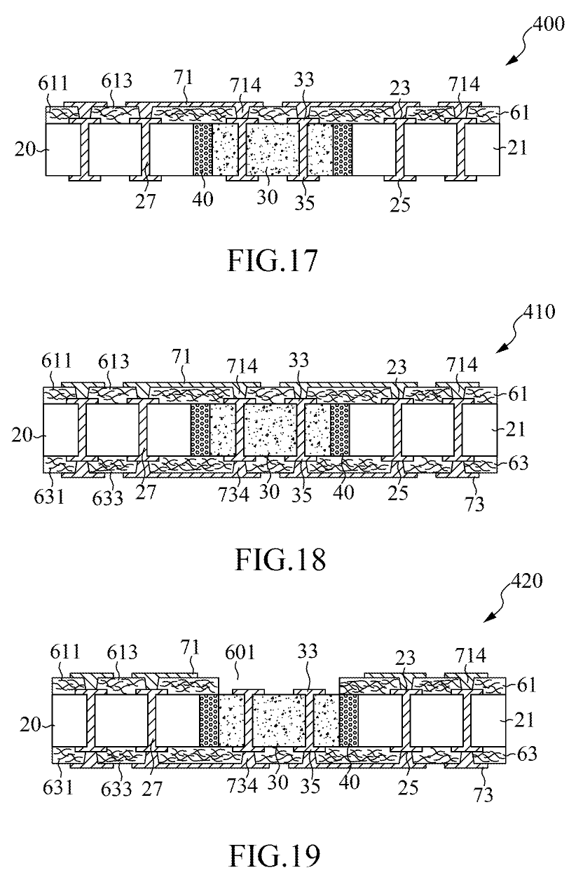

FIG. 17 is a cross-sectional view of a wiring board in accordance with the fourth embodiment of the present invention.

For purposes of brevity, any description in the Embodiments above is incorporated herein insofar as the same is applicable, and the same description need not be repeated.

The wiring board 400 is similar to that illustrated in FIG. 6, except that it further includes a top crack inhibiting structure 61 and a top routing trace 71 formed in an alternate fashion from above. The top crack inhibiting structure 61 covers the top surface of the core substrate 20, the top side of the heat dissipation slug 30, and the top surface of the modified binding matrix 40 to provide protection from above. The top routing trace 71 extends from the top circuit layer 23 of the core substrate 20 and the top metal layer 33 of the heat dissipation slug 30 in the upward direction, extends through the top crack inhibiting structure 61 to form top metal vias 714 in direct contact with the top circuit layer 23 and the top metal layer 33, and extends laterally on the top crack inhibiting structure 61. In this embodiment, the top crack inhibiting structure 61 includes a top continuous interlocking fiber sheet 611 that covers the interfaces between the core substrate 20 and the modified binding matrix 40 and between the heat dissipation slug 30 and the modified binding matrix 40 from above, and further laterally extends over and covers the top surface of the core substrate 20, the top side of the heat dissipation slug 30, and the top surface of the modified binding matrix 40. The continuous interlocking fibers can be carbon fibers, silicon carbide fibers, glass fibers, nylon fibers, polyester fibers or polyamide fibers. By virtue of the fiber interlocking configuration, the top crack inhibiting structure 61 can prevent detachment induced by cracks formed within the modified binding matrix 40, and also serve as a crack stopper to restrain undesirable cracks from extending to the top routing trace 71. As a result, the reliability of the top routing trace 71 spaced from the modified binding matrix 40 by the top crack inhibiting structure 61 can be ensured. In this illustration, the top crack inhibiting structure 61 further includes a top binding resin 613, and the top continuous interlocking fiber sheet 611 is impregnated in the top binding resin 613. Accordingly, the top routing trace 71 is attached to the top binding resin 613 and thermally conductible to the heat dissipation slug 30 and electrically connected to the top circuit layer 23 and the top metal layer 33 through the top metal vias 714 penetrating through the top crack inhibiting structure 61.

FIG. 18 is a cross-sectional view of another aspect of the wiring board in accordance with the fourth embodiment of the present invention. The wiring board 410 is similar to that illustrated in FIG. 17, except that it further includes a bottom crack inhibiting structure 63 and a bottom routing trace 73 formed in an alternate fashion from below. The bottom crack inhibiting structure 63 covers the bottom surface of the core substrate 20, the bottom side of the heat dissipation slug 30, and the bottom surface of the modified binding matrix 40 to provide protection from below. The bottom routing trace 73 extends laterally on the bottom crack inhibiting structure 63, and is thermally conductible to the bottom metal layer 33 of the heat dissipation slug 30 and electrically connected to the bottom circuit layer 23 of the core substrate 20 through the bottom metal vias 734. Like the top crack inhibiting structure 61, the bottom crack inhibiting structure 63 may include a bottom continuous interlocking fiber sheet 631 that covers the interfaces between the core substrate 20 and the modified binding matrix 40 and between the heat dissipation slug 30 and the modified binding matrix 40 from below, and further laterally extends below and covers the bottom surface of the core substrate 20, the bottom side of the heat dissipation slug 30 and the bottom surface of the modified binding matrix 40. Accordingly, the interlocking configuration formed in the bottom crack inhibiting structure 63 can restrain any cracks from extending into the bottom crack inhibiting structure 63 so as to ensure reliability of the bottom routing trace 73 under the bottom crack inhibiting structure 63. By virtue of the dual protection from the top crack inhibiting structure 61 and the bottom crack inhibiting structure 63, the segregation induced by cracks formed within the modified binding matrix 40 can be prevented or restrained. In this illustration, the bottom crack inhibiting structure 63 further includes a bottom binding resin 633, and the bottom continuous interlocking fiber sheet 631 is impregnated in the bottom binding resin 633.

FIG. 19 is a cross-sectional view of yet another aspect of the wiring board in accordance with the fourth embodiment of the present invention. The wiring board 420 is similar to that illustrated in FIG. 18, except that the top side of the heat dissipation slug 30 is exposed from above. In this illustration, a selected portion of the top crack inhibiting structure 61 is removed to form a cavity 601 aligned with the heat dissipation slug 30. As a result, the top crack inhibiting structure 61 has an inner sidewall that laterally surrounds the cavity 601 from which the top surface of the heat dissipation slug 30 is exposed for device connection.

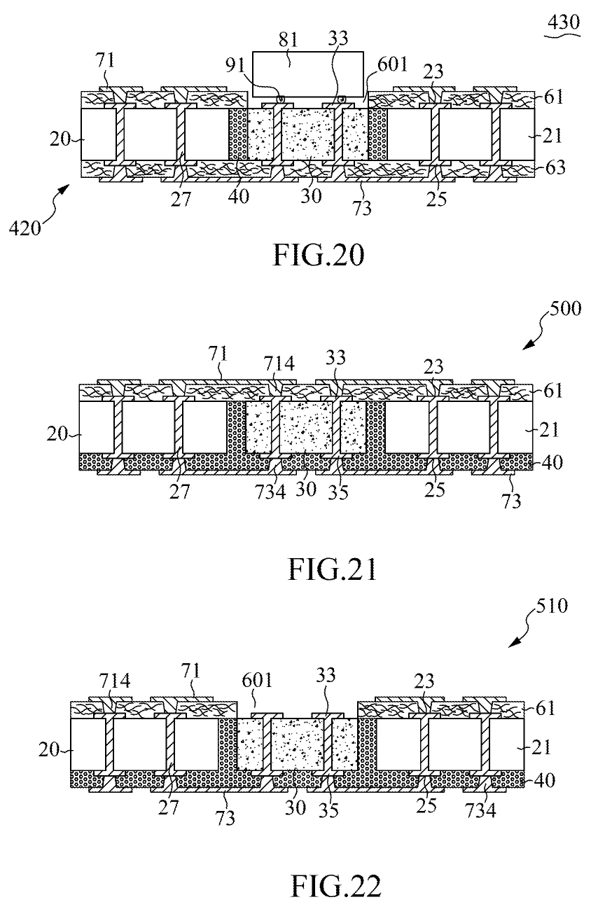

FIG. 20 is a cross-sectional view of a semiconductor assembly 430 with a semiconductor device 81 electrically connected to the wiring board 420 illustrated in FIG. 19. The semiconductor device 81 is disposed into the cavity 601 and flip-chip mounted on the heat dissipation slug 30 through bumps 91. As a result, the semiconductor device 81 is electrically connected to and thermally conductible to the bottom routing trace 73 through the bumps 91 in contact with the top metal layer 33 of the heat dissipation slug 30.

### Embodiment 5

FIG. 21 is a cross-sectional view of a wiring board in accordance with the fifth embodiment of the present invention.

For purposes of brevity, any description in the Embodiments above is incorporated herein insofar as the same is applicable, and the same description need not be repeated.

The wiring board 500 is similar to that illustrated in FIG. 17, except that the modified binding matrix 40 further covers the bottom surface of the core substrate 20 and the bottom side of the heat dissipation slug 30, and the wiring board 500 further includes a bottom routing trace 73 formed under the modified binding matrix 40 from below. The bottom routing trace 73 laterally extends below the core substrate 20 and the heat dissipation slug 30 and is thermally conductible to the heat dissipation slug 30 and electrically connected to the core substrate 20 and the heat dissipation slug 30 through bottom metal vias 734 in contact with the bottom circuit layer 25 of the core substrate 20 and the bottom metal layer 35 of the heat dissipation slug 30.

FIG. 22 is a cross-sectional view of another aspect of the wiring board in accordance with the fifth embodiment of the present invention. The wiring board 510 is similar to that illustrated in FIG. 21, except that the top side of the heat dissipation slug 30 is exposed from a cavity 601. In this illustration, the cavity 601 is aligned with the heat dissipation slug 30 to expose the top side of the heat dissipation slug 30 for device attachment.

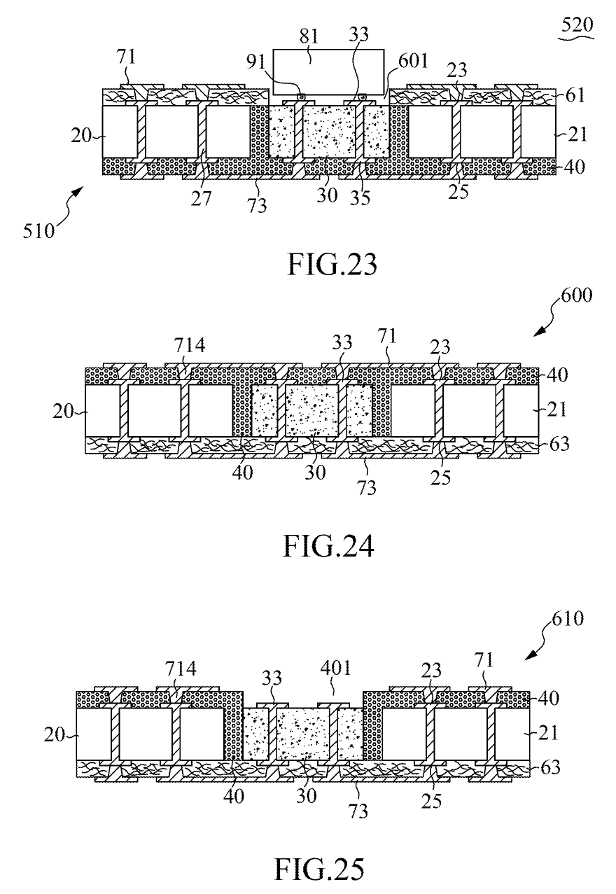

FIG. 23 is a cross-sectional view of a semiconductor assembly 520 with a semiconductor device 81 electrically connected to the wiring board 510 illustrated in FIG. 22. The semiconductor device 81 is face-down disposed in the cavity 601 and thermally conductible to and electrically connected to the top metal layer 33 of the heat dissipation slug 30 through bumps 91.

### Embodiment 6

FIG. 24 is a cross-sectional view of a wiring board in accordance with the sixth embodiment of the present invention.

For purposes of brevity, any description in the Embodiments above is incorporated herein insofar as the same is applicable, and the same description need not be repeated.

The wiring board 600 is similar to that illustrated in FIG. 13, except that it further includes a bottom crack inhibiting structure 63 and a bottom routing trace 73 formed in an alternate fashion from below. The bottom crack inhibiting structure 63 cover the bottom surface of the core substrate 20, the bottom side of the heat dissipation slug 30 and the bottom surface of the modified binding matrix 40. The bottom routing trace 73 is spaced from interfaces between the core substrate 20 and the modified binding matrix 40 and between the heat dissipation slug 30 and the modified binding matrix 40 and thermally conductible to the heat dissipation slug 30 and electrically coupled to the core substrate 20.

FIG. 25 is a cross-sectional view of another aspect of the wiring board in accordance with the sixth embodiment of the present invention. The wiring board 610 is similar to that illustrated in FIG. 24, except that a selected portion of the modified binding matrix 40 is removed to form a cavity 401 that is aligned with the heat dissipation slug 30 to expose the top side of the heat dissipation slug 30 for device attachment.

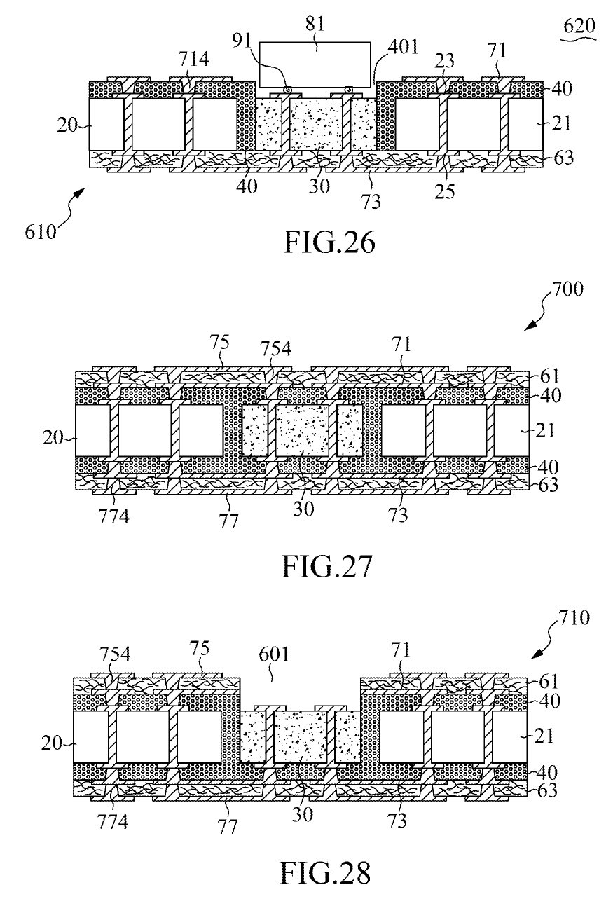

FIG. 26 is a cross-sectional view of a semiconductor assembly 620 with a semiconductor device 81 electrically connected to the wiring board 610 illustrated in FIG. 25. The semiconductor device 81 is face-down disposed in the cavity 401 and thermally conductible to and electrically connected to the heat dissipation slug 30 through bumps 91.

### Embodiment 7

FIG. 27 is a cross-sectional view of a wiring board in accordance with the seventh embodiment of the present invention.

For purposes of brevity, any description in the Embodiments above is incorporated herein insofar as the same is applicable, and the same description need not be repeated.

The wiring board 700 is similar to that illustrated in FIG. 14, except that it further includes a top crack inhibiting structure 61 and a top routing trace 75 formed in an alternate fashion from above and a bottom crack inhibiting structure 63 and a bottom routing trace 77 formed in an alternate fashion from below. The top crack inhibiting structure 61 covers the modified binding matrix 40 and the top routing trace 71 from above. The bottom crack inhibiting structure 63 covers the modified binding matrix 40 and the bottom routing trace 73 from below. The top routing trace 75 laterally extends on the top crack inhibiting structure 61 and is electrically connected to the top routing trace 71 through top metal vias 754 in the top crack inhibiting structure 61. The bottom routing trace 77 laterally extends under the bottom crack inhibiting structure 63 and is electrically connected to the bottom routing trace 73 through bottom metal vias 774 in the bottom crack inhibiting structure 63.

FIG. 28 is a cross-sectional view of another aspect of the wiring board in accordance with the seventh embodiment of the present invention. The wiring board 710 is similar to that illustrated in FIG. 27, except that selected portions of the modified binding matrix 40 and the top crack inhibiting structure 61 are removed to form a cavity 601. In this illustration, the modified binding matrix 40 and the top crack inhibiting structure 61 have inner sidewalls that laterally surround the cavity 601 from which the top side of the heat dissipation slug 30 is exposed.

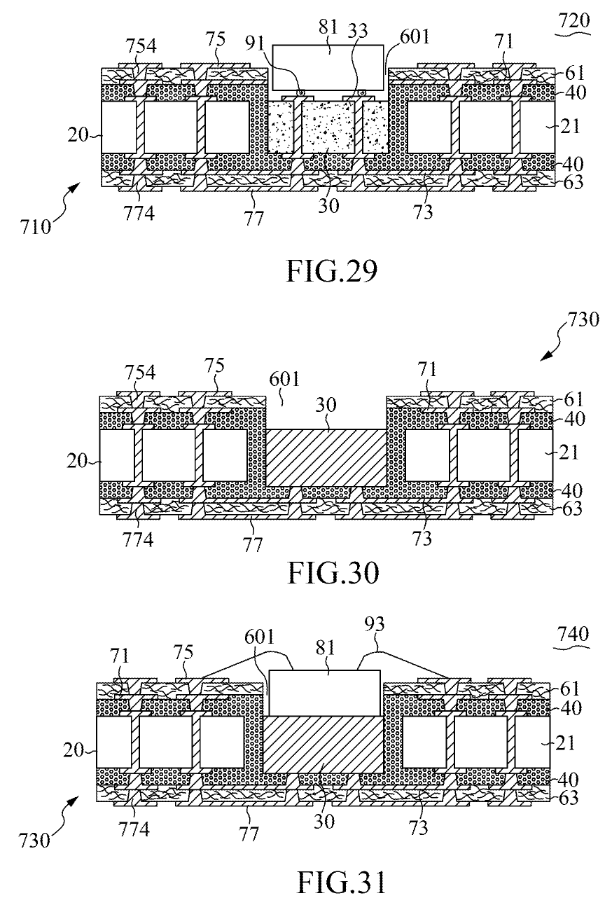

FIG. 29 is a cross-sectional view of a semiconductor assembly 720 with a semiconductor device 81 electrically connected to the wiring board 710 illustrated in FIG. 28. The semiconductor device 81 is face-down disposed in the cavity 601 and thermally conductible to and electrically connected to the bottom routing traces 73, 77 though bumps 91 between the semiconductor device 81 and the top metal layer 33 of the heat dissipation slug 30.

FIG. 30 is a cross-sectional view of yet another aspect of the wiring board in accordance with the seventh embodiment of the present invention. The wiring board 630 is similar to that illustrated in FIG. 28, except that the heat dissipation slug 30 is made of metal.

FIG. 31 is a cross-sectional view of a semiconductor assembly 740 with a semiconductor device 81 electrically connected to the wiring board 730 illustrated in FIG. 30. The semiconductor device 81 is disposed in the cavity 601 and face-up mounted on the heat dissipation slug 30 and electrically connected to the top routing trace 75 through bonding wires 93. As a result, the semiconductor device 81 is thermally conductible to the bottom routing traces 73, 77 through the heat dissipation slug 30 and electrically connected to the bottom routing traces 73, 77 through the bonding wires 93, the top routing traces 71, 75 and the core substrate 20.

As illustrated in the aforementioned embodiments, a distinctive wiring board is configured to exhibit improved reliability. Preferably, the wiring board mainly includes a heat dissipation slug, a core substrate and a modified binding matrix. Optionally, the wiring board of the present invention may further include a top routing trace spaced from interfaces between the modified binding matrix and the heat dissipation slug and between the modified binding matrix and the core substrate by the modified binding matrix or/and a top crack inhibiting structure, or/and further include a bottom routing trace spaced from the interfaces by the modified binding matrix or/and a bottom crack inhibiting structure. Additionally, the wiring board of the present invention may have a cavity aligned with the top side of the heat dissipation slug and laterally surrounded by the modified binding matrix or/and the top crack inhibiting structure, and the bottom surface of the core substrate and the bottom side of the heat dissipation slug are covered by the modified binding matrix or/and the bottom crack inhibiting structure.

The heat dissipation slug is a non-electronic component and may have a thermal conductivity higher than 10 W/mk for enhanced thermal performance. In a preferred embodiment, the heat dissipation slug includes an electrical isolator, a top metal layer at its top side, a bottom metal layer at its bottom side, and optionally metallized through vias for electrical connection between the top metal layer and the bottom metal layer. In order to enhance the structural strength and help to maintain the flatness of the wiring board when under external or internal strain/stress, the heat dissipation slug may have an elastic modulus higher than 200 GPa. Furthermore, in flip-chip assembly application, the heat dissipation slug preferably has a coefficient of thermal expansion lower than 10 ppm/° C. so as to reduce chip/board CTE mismatch. As a result, the heat dissipation slug, having CTE matching a semiconductor device to be assembled thereon, provides a CTE-compensated platform for the semiconductor device, and thus internal stresses caused by CTE mismatch can be largely compensated or reduced.

The core substrate is positioned around the peripheral sidewall of the heat dissipation slug and includes top and bottom circuit layers to provide electrical contacts at its two opposite sides. Optionally, the top circuit layer of the core substrate may be electrically coupled to the top metal layer of the heat dissipation slug through a top plated layer that laterally extends on the modified binding matrix in the gap and contact the top metal layer and the top circuit layer. In a preferred embodiment, the core substrate further includes metallized through holes for electrical connection between the top circuit layer and the bottom circuit layer. As a result, the core substrate can provide signal vertical transduction pathways and optionally provide ground/power plane for power delivery and return. Additionally, the inner sidewall of the core substrate is spaced from the peripheral sidewall of the heat dissipation slug by a gap width of preferably more than 10 micrometers (more preferably 25 micrometers or more), so that the modified binding matrix in the gap can have enough width to absorb stress.

The modified binding matrix fills the gap between the heat dissipation slug and the core substrate and is bonded to the peripheral sidewall of the heat dissipation slug and the inner sidewall of the core substrate. Typically, the modified binding matrix may have a high CTE resin adhesive to provide mechanical bonds between the heat dissipation slug and the core substrate. As the CTE of the resin adhesive is extremely higher than those of the heat dissipation slug and the core substrate, it is prone to crack induced by internal expansion and shrinkage during thermal cycling in a confined area. In order to reduce the risk of adhesive cracking, the modified binding matrix contains lower CTE modulators mixed in the resin adhesive. Preferably, the modulators are in an amount of at least 30% (preferably 50% or more) by volume based on the total volume of the gap, and the difference in CTE between the resin adhesive and the modulators is 10 ppm/° C. or more so as to exhibit significant effect. As a result, the internal expansion and shrinkage of the modified binding matrix during thermal cycling can be alleviated so as to restrain its cracking. Furthermore, for effectively releasing thermo-mechanical induced stress, the modified binding matrix preferably has a sufficient width of more than 10 micrometers (more preferably 25 micrometers or more) in the gap to absorb the stress. In the aspect of the core substrate being thinner than the heat dissipation slug, the modified binding matrix may extend outside of the gap and further cover the top surface or/and the bottom surface of the core substrate. By the lateral extension of the modified binding matrix over one or two surfaces of the core substrate, the interfacial stress between the modified binding matrix and the heat dissipation slug and between the modified binding matrix and the core substrate can be dispersed so as to conduce to further reduction of cracking risk. Further, the modified binding matrix may also cover the top side or/and the bottom side of the heat dissipation slug, or have an inner sidewall that laterally surrounds a cavity from which the top side of the heat dissipation slug is exposed for device attachment.

The top crack inhibiting structure and the bottom crack inhibiting structure are electrically insulating and can serve as crack stoppers to restrain undesirable cracks formed in the modified binding matrix. In a preferred embodiment, the top crack inhibiting structure includes a top binding resin and a top continuous interlocking fiber sheet impregnated in the top binding resin, whereas the bottom crack inhibiting structure includes a bottom binding resin and a bottom continuous interlocking fiber sheet impregnated in the bottom binding resin. The top and bottom continuous interlocking fiber sheets cover top and bottom ends of the interfaces between the modified binding matrix and the heat dissipation slug and between the modified binding matrix and the core substrate, respectively. More specifically, the top continuous interlocking fiber sheet can laterally extend above and cover the top surface of the core substrate, the top side of the heat dissipation slug and the top surface of the modified binding matrix, whereas the bottom continuous interlocking fiber sheet can laterally extend below and cover the bottom surface of the core substrate, the bottom side of the heat dissipation slug and the bottom surface of the modified binding matrix. Alternatively, the top continuous interlocking fiber sheet may have an inner sidewall that laterally surrounds a cavity from which the top side of the heat dissipation slug is exposed. By interlocking configuration of the top and bottom continuous interlocking fiber sheets, the risk of cracking in the modified binding matrix can be further reduced. Even if cracks are generated at interfaces or/and formed in the modified binding matrix, the interlocking fiber sheets can also serve as a crack stopper to restrain the cracks from extending into the top and bottom crack inhibiting structures so as to ensure reliability of top and bottom routing traces on the top and bottom crack inhibiting structures.

The top routing trace is a patterned metal layer laterally extending above the top side of the heat dissipation slug and the top surface of the core substrate and spaced from the interfaces by the top crack inhibiting structure or the modified binding matrix. By virtue of the top crack inhibiting structure or the modified binding matrix between the top routing trace and the interfaces, the reliability of the top routing trace can be ensured. Likewise, the bottom routing trace is a patterned metal layer laterally extending below the bottom side of the heat dissipation slug and the bottom surface of the core substrate and spaced from the interfaces by the bottom crack inhibiting structure or the modified binding matrix to ensure the reliability of the bottom routing trace. In a preferred embodiment, the top routing trace is thermally conductible to the top metal layer of the heat dissipation slug and electrically connected to the top circuit layer of the core substrate through top metal vias, whereas the bottom routing trace is thermally conductible to the bottom metal layer of the heat dissipation slug and electrically connected to the bottom circuit layer of the core substrate through bottom metal vias.

The present invention also provides a semiconductor assembly in which a semiconductor device such as chip is mounted over the heat dissipation slug of the aforementioned wiring board and electrically coupled to the aforementioned wiring board. Specifically, the semiconductor device can be electrically connected to the wiring board using various using a wide variety of connection media including bumps (such as gold or solder bumps) or bonding wires. For instance, in the aspect of the heat dissipation slug being exposed from the cavity laterally surrounded by the modified binding matrix and/or the top crack inhibiting structure, the semiconductor device can be disposed in the cavity and mounted on the top side of the heat dissipation slug, and electrically coupled to the top metal layer of the heat dissipation slug through bumps or electrically coupled to the top routing trace through bonding wires. As a result, the heat generated by the semiconductor device can be conducted away through the heat dissipation slug and the bottom routing trace.

The assembly can be a first-level or second-level single-chip or multi-chip device. For instance, the assembly can be a first-level package that contains a single chip or multiple chips. Alternatively, the assembly can be a second-level module that contains a single package or multiple packages, and each package can contain a single chip or multiple chips. The semiconductor device can be a packaged or unpackaged chip. Furthermore, the semiconductor device can be a bare chip, or a wafer level packaged die, etc.

The term “cover” refers to incomplete or complete coverage in a vertical and/or lateral direction. For instance, in a preferred embodiment, the top crack inhibiting structure covers the top side of the heat dissipation slug and the top surface of the core substrate as well as the modified binding matrix regardless of whether another element (such as the modified binding matrix) is between the top crack inhibiting structure and the heat dissipation slug and between the top crack inhibiting structure and the core substrate.

The phrases “mounted on” and “ mounted over” include contact and non-contact with a single or multiple support element(s). For instance, in a preferred embodiment, the semiconductor device can be mounted over the top side of the heat dissipation slug regardless of whether the semiconductor device is separated from the heat dissipation slug by the bumps and the top crack inhibiting structure.

The phrases “electrical connection”, “electrically connected” and “electrically coupled” refer to direct and indirect electrical connection. For instance, in a preferred embodiment, the top routing trace can be electrically connected to the bottom routing trace by the core substrate but does not contact the bottom routing trace.

The wiring board made by this method is reliable, inexpensive and well-suited for high volume manufacture. The manufacturing process is highly versatile and permits a wide variety of mature electrical and mechanical connection technologies to be used in a unique and improved manner. The manufacturing process can also be performed without expensive tooling. As a result, the manufacturing process significantly enhances throughput, yield, performance and cost effectiveness compared to conventional techniques.

The embodiments described herein are exemplary and may simplify or omit elements or steps well-known to those skilled in the art to prevent obscuring the present invention. Likewise, the drawings may omit duplicative or unnecessary elements and reference labels to improve clarity.

The embodiments described herein are exemplary and may simplify or omit elements or steps well-known to those skilled in the art to prevent obscuring the present invention. Likewise, the drawings may omit duplicative or unnecessary elements and reference labels to improve clarity.

What is claimed is:

1. A wiring board, comprising:
a core substrate having a top circuit layer at a top surface thereof, a bottom circuit layer at a bottom surface thereof and an aperture extending from the top surface to the bottom surface thereof;
a heat dissipation slug disposed in the aperture of the core substrate;
a resin adhesive that has a first coefficient of thermal expansion and fills a gap between a peripheral sidewall of the heat dissipation slug and an inner sidewall of the aperture; and
a plurality of modulators that have a second coefficient of thermal expansion lower than the first coefficient of thermal expansion and are dispensed in the resin adhesive to form a modified binding matrix having a width of more than 10 micrometers in the gap, wherein a coefficient of thermal expansion of the modified binding matrix is lower than 40 ppm/° C.

2. The wiring board of claim 1, wherein the core substrate has a third coefficient of thermal expansion and the heat dissipation slug has a fourth coefficient of thermal expansion, wherein the first coefficient of thermal expansion is higher than both the third and the fourth coefficients of thermal expansion.

3. The wiring board of claim 1, wherein the modified binding matrix extends outside of the gap and further covers the top surface of the core substrate.

4. The wiring board of claim 3, further comprising a top routing trace disposed over the modified binding matrix and electrically coupled to the top circuit layer of the core substrate.

5. The wiring board of claim 4, wherein the modified binding matrix further covers the bottom surface of the core substrate.

6. The wiring board of claim 5, further comprising a bottom routing trace disposed under the modified binding matrix and electrically coupled to the bottom circuit layer of the core substrate.

7. The wiring board of claim 6, wherein the modified binding matrix further covers a bottom side of the heat dissipation slug, and the bottom routing trace is thermally conductible to the bottom side of the heat dissipation slug.

8. The wiring board of claim 7, wherein the modified binding matrix further covers a top side of the heat dissipation slug, and the top routing trace is thermally conductible to the top side of the heat dissipation slug.

9. The wiring board of claim 7, wherein the modified binding matrix has an inner sidewall that laterally surrounds a cavity from which the top side of the heat dissipation slug is exposed.

10. The wiring board of claim 1, further comprising a top crack inhibiting structure, wherein the top crack inhibiting structure includes a top continuous interlocking fiber sheet that covers a top surface of the modified binding matrix in the gap between the heat dissipation slug and the core substrate.

11. The wiring board of claim 10, wherein the top continuous interlocking fiber sheet further laterally extends above and covers the top surface of the core substrate, and the wiring board further comprises a top routing trace disposed over the top crack inhibiting structure and electrically coupled to the top circuit layer of the core substrate.

12. The wiring board of claim 11, further comprising a bottom crack inhibiting structure, wherein the bottom crack inhibiting structure includes a bottom continuous interlocking fiber sheet that covers a bottom surface of the modified binding matrix in the gap between the heat dissipation slug and the core substrate.

13. The wiring board of claim 12, wherein the bottom continuous interlocking fiber sheet further laterally extends below and covers the bottom surface of the core substrate and a bottom side of the heat dissipation slug, and the wiring board further comprises a bottom routing trace disposed under the bottom crack inhibiting structure and electrically coupled to the bottom circuit layer of the core substrate and thermally conductible to the bottom side of the heat dissipation slug.

14. The wiring board of claim 13, wherein the top crack inhibiting structure has an inner sidewall that laterally surrounds a cavity from which a top side of the heat dissipation slug is exposed.

15. The wiring board of claim 13, wherein the top continuous interlocking fiber sheet further laterally extends above and covers the a top side of the heat dissipation slug, and the top routing trace is thermally conductible to the top side of the heat dissipation slug.

16. The wiring board of claim 1, wherein the heat dissipation slug is an electrical isolator and has a top metal layer and a bottom metal layer at top and bottom sides thereof, respectively.

17. The wiring board of claim 16, wherein the top metal layer is electrically coupled to the bottom metal layer.

18. The wiring board of claim 16, further comprising a top plated layer that laterally extends on the modified binding matrix in the gap and electrically connects the top metal layer of the heat dissipation slug with the top circuit layer of the core substrate.

19. The wiring board of claim 18, wherein the modified binding matrix extends outside of the gap and further covers the bottom surface of the core substrate.

20. A semiconductor assembly, comprising:
the wiring board of claim 9; and
a semiconductor device disposed in the cavity and mounted on the heat dissipation slug and electrically coupled to the wiring board.

21. A semiconductor assembly, comprising:
the wiring board of claim 14; and
a semiconductor device disposed in the cavity and mounted on the heat dissipation slug and electrically coupled to the wiring board.
